(19) United States
(12) Patent Application Publication
(10) Pub. No.: US 2007/0024161 A1
(43) Pub. Date: Feb. 1, 2007

(54) PIEZOELECTRIC DEVICE AND METHOD OF MANUFACTURING PIEZOELECTRIC DEVICE

(75) Inventors: Yugo Koyama, Suwa-shi, Nagano-ken (JP); Jitsuo Iwamoto, Suwa-shi, Nagano-ken (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/460,057

(22) Filed: Jul. 26, 2006

(30) Foreign Application Priority Data
Jul. 26, 2005 (JP) 2005-215474
Jul. 26, 2005 (JP) 2005-215475

(51) Int. Cl. H01L 41/053

(52) U.S. Cl. 310/348

(57) ABSTRACT

A piezoelectric device includes, a substrate having a wiring pattern, a piezoelectric element package disposed on one surface side of the substrate and having a piezoelectric element housed therein, a circuit module, in which a module substrate mounts a circuit element, disposed on one surface side of the substrate, and a resin member covering the piezoelectric element package and the circuit module from the substrate.

### BACKGROUND

1. Technical Field

The present invention relates to a piezoelectric device provided with a piezoelectric element and a circuit element, and a method of manufacturing the piezoelectric device.

2. Related Art

As a piezoelectric device such as a crystal oscillation, there is known a structure, as described in an example of related art, in which a substrate has a crystal unit package and circuit elements mounted thereon, the circuit elements constituting an oscillation circuit such as a transistor, resistance, capacitor, and thermistor. Generally, when the crystal unit package and the circuit elements are set on the substrate, cream solder is applied to a mounting pattern of the substrate, and they are soldered at one time to the substrate by a reflow method.

JP-A11-355047 is the example of the related art.

In the case that the crystal unit package and a plurality of circuit elements are set on the substrate, especially in a case of setting small circuit elements, defective soldering has tended to occur. When the defective soldering occurs, soldering is performed again. This has led to a decrease of productivity and such a problem of further shifting a frequency of an oscillation device.

Moreover, there has been a problem that, in manufacturing the piezoelectric device, a frequency of a piezoelectric element such as a crystal oscillation piece shifts and deviates from a desired frequency due to an effect of heating during a process. Since the frequency cannot be adjusted after the piezoelectric element is sealed in a package, the frequency of the piezoelectric element is generally set with some allowance considering a frequency shift in a subsequent process. Especially in manufacturing a piezoelectric device requiring a high frequency accuracy, each manufacturing process is managed severely so that the frequency shift is small in the manufacturing process, and variations thereof are suppressed as much as possible. This has caused a requirement for more man-hours and an increase of production cost in the manufacturing process.

### SUMMARY

An advantage of some aspects of the invention is to provide a piezoelectric device with an improved productivity and excellent characteristics, and a method of manufacturing the piezoelectric device.

According to a first aspect of the invention, a piezoelectric device includes a substrate having a wiring pattern, a piezoelectric element package disposed on one surface side of the substrate and having a piezoelectric element housed therein, a circuit module, in which a module substrate mounts a circuit element, disposed on the one surface side of the substrate, and a resin member covering the piezoelectric element package and the circuit module from the substrate.

In manufacturing the piezoelectric device, since the circuit elements can be mounted on the module substrate in advance, a heating condition for a reflow and others may be matched with the circuit elements. Therefore, the defective soldering may be reduced. The piezoelectric element package and the circuit module may be set on the substrate of the piezoelectric device thereafter. There may be no require for soldering again due to the defective soldering of the circuit elements. In this manner, it may be possible to improve productivity of manufacturing the piezoelectric device and provide the piezoelectric device with less frequency shift when setting the piezoelectric element package on the substrate, and excellent characteristics.

Furthermore, since the resin member is formed so as to cover the piezoelectric element package and the circuit module from the substrate, it may play a role of reinforcing the substrate even if the substrate is made thinner. Therefore, while maintaining strength as the piezoelectric device, a thickness thereof may be reduced.

In the above-mentioned piezoelectric device, it is preferable that the piezoelectric element package have a transparent lid member at least a part of which is exposed to the outside.

In this constitution, the transparent lid member of the piezoelectric element package is formed so as to be exposed to the outside. Therefore, even after assembling the piezoelectric device, it may be possible to adjust a frequency of the piezoelectric element inside the piezoelectric element package by irradiating laser beam to the inside of the package from the outside through the lid member.

In this manner, the frequency may be adjusted easily after assembling the piezoelectric device, which has been impossible in the past. Therefore, it may be possible to provide the piezoelectric device the frequency of which can be set to a desired frequency even when a high frequency accuracy is required.

According to a second aspect of the invention, a method of manufacturing a piezoelectric device, in which a substrate having a plurality of wiring patterns of a piezoelectric device disposed thereon is prepared, includes fixing a circuit module in which a module substrate mounts a circuit element to each of the wiring patterns on one surface side of the substrate, fixing a piezoelectric element package having a piezoelectric element housed therein to each of the wiring patterns on one surface side of the substrate, performing resin-molding so as to cover the circuit module and the piezoelectric element package of each of the piezoelectric devices, and cutting the substrate into a plurality of piezoelectric devices.

In the manufacturing method, setting the circuit elements on the substrate of the piezoelectric device is made by setting the circuit module which has mounted the circuit elements in advance. Therefore, the piezoelectric device may be easily assembled. Further, there may be no require for soldering again due to the defective soldering of the circuit elements, and productivity may be improved.

Further, a plurality of piezoelectric devices are manufactured on one substrate by fixing the circuit modules and the piezoelectric element packages, and resin-molding. Finally the piezoelectric devices are cut into individual pieces by dicing or the like. Therefore, productivity may be further improved.

In the above-mentioned method of manufacturing the piezoelectric device, it is preferable that, in resin-molding, the circuit module and the piezoelectric element package of each of the piezoelectric devices be resin-molded such that at least a part of a transparent lid member of the piezoelectric element package is exposed to the outside.

In the method of manufacturing the piezoelectric device, the transparent lid member of the piezoelectric element package is formed so as to be exposed to the outside, in resin-molding in a state of fixing the piezoelectric element package and the circuit module to the substrate. Thus a frequency of the piezoelectric element inside the piezoelectric element package may be adjusted by irradiating laser beam to the inside of the package from the outside through the lid member.

That is, in the manufacturing process of the piezoelectric device, when the frequency of the piezoelectric element is deviated from a desired frequency range, the frequency of the piezoelectric element may be adjusted by irradiating laser beam to a part of an electrode of the piezoelectric element to delete the part.

According to a third aspect of the invention, a method of manufacturing a piezoelectric device, in which a substrate having a wiring pattern disposed thereon is prepared, includes fixing a circuit module in which a module substrate mounts a circuit element to the wiring pattern on one surface side of the substrate, fixing a piezoelectric element package having a piezoelectric element housed therein to the wiring pattern on one surface side of the substrate, and performing resin-molding so as to cover the circuit module and the piezoelectric element package.

In the manufacturing method, setting the circuit elements on the substrate of the piezoelectric device is made by setting the circuit module which has mounted the circuit elements in advance. Therefore, the piezoelectric device may be easily assembled. Further, there may be no require for soldering again due to the defective soldering of the circuit elements, and productivity may be improved.

According to a fourth aspect of the invention, a piezoelectric device includes a substrate having a wiring pattern, a piezoelectric element package which is disposed on one surface side of the substrate, has a piezoelectric element housed therein, and is provided with a transparent lid member, a circuit element disposed on one surface side of the substrate, a resin member covering the piezoelectric element package and the circuit element from the substrate. At least a part of the transparent lid member of the piezoelectric element package is exposed to the outside.

In manufacturing a piezoelectric device in this constitution, the transparent lid member of the piezoelectric element package is formed so as to be exposed to the outside. Therefore, even after assembling the piezoelectric device, the frequency may be adjusted by irradiating laser beam to the inside of the package from the outside through the lid member thereby to remove a part of an electrode of the piezoelectric element.

In this manner, the frequency may be adjusted easily after assembling the piezoelectric device, which has been impossible in the past. Therefore, it may be possible to provide the piezoelectric device the frequency of which can be set to a desired frequency even when a high frequency accuracy is required.

Furthermore, since the resin member is formed so as to cover the piezoelectric element package and the circuit module from the substrate, it may play a role of reinforcing the substrate even if the substrate is made thinner. Therefore, while maintaining strength as the piezoelectric device, a thickness thereof may be reduced.

According to a fifth aspect of the invention, a method of manufacturing a piezoelectric device, in which a substrate having a wiring pattern disposed thereon is prepared, includes fixing a circuit element to one surface side of the substrate, fixing a piezoelectric element package having a piezoelectric element housed therein to one surface side of the substrate, and performing resin-molding the circuit element and the piezoelectric element package such that at least a part of a transparent lid member of the piezoelectric element package is exposed to the outside.

In the method of manufacturing the piezoelectric device, the transparent lid member of the piezoelectric element package is formed so as to be exposed to the outside, in resin-molding in a state of fixing the piezoelectric element package and the circuit element to the substrate. Thus, a frequency of the piezoelectric element inside the piezoelectric element package may be adjusted by irradiating laser beam to the inside of the package from the outside through the lid member.

That is, in the manufacturing process of the piezoelectric device, when the frequency of the piezoelectric element is deviated from a desired frequency range, the frequency of the piezoelectric element may be adjusted by irradiating laser beam to a part of an electrode of the piezoelectric element to delete the part.

In the method of manufacturing the piezoelectric device, it is preferable that in a stage after resin-molding, a frequency of the piezoelectric element be adjusted by irradiating laser beam to the inside of the package through the transparent lid member exposed to the outside.

In the method of manufacturing the piezoelectric device, in a stage after resin-molding, the frequency may be adjusted by irradiating laser beam to the inside of the package through the transparent lid member exposed to the outside thereby to remove a part of an electrode of the piezoelectric element. Especially, after a process affected by heat and pressure during the manufacturing process, the frequency of the piezoelectric element inside the piezoelectric element package may be adjusted. Therefore, there may arise no problem that a frequency shift occurs to make the product defective after manufacturing as in the past, and manufacturing yield may be improve.

According to a sixth aspect of the invention, a method of manufacturing a piezoelectric device, in which a substrate having a plurality of wiring patterns of a piezoelectric device disposed thereon is prepared, includes fixing a circuit element to each of the wiring patterns on one surface side of the substrate, fixing a piezoelectric element package having a piezoelectric element housed therein to each of the wiring patterns on one surface side of the substrate, performing resin-molding the circuit element and the piezoelectric element package of each of the piezoelectric devices such that at least a part of a transparent lid member of the piezoelectric element package is exposed to the outside, and cutting the substrate into a plurality of piezoelectric devices.

In the method of manufacturing the piezoelectric device, the transparent lid member of the piezoelectric element package is formed so as to be exposed to the outside, in resin-molding in a state of fixing the piezoelectric element package and the circuit elements to the substrate. Thus, the frequency may be adjusted by irradiating laser beam to the inside of the package from the outside through the lid member thereby to remove a part of an electrode of the piezoelectric element.

Further, a plurality of piezoelectric devices are manufactured on one substrate by fixing the circuit elements and the piezoelectric element packages, and resin-molding. Finally the piezoelectric devices are cut into individual pieces by dicing or the like. Therefore, productivity may be further improved.

In the method of manufacturing the piezoelectric device, it is preferable that in a stage after resin-molding, a frequency of the piezoelectric element be adjusted by irradiating laser beam to the inside of the package through the transparent lid member exposed to the outside.

In the method of manufacturing the piezoelectric device, in a stage after resin-molding, the frequency may be adjusted by irradiating laser beam to the inside of the package through the transparent lid member exposed to the outside thereby to remove a part of an electrode of the piezoelectric element. Especially, after a process affected by heat and pressure during the manufacturing process, the frequency of the piezoelectric element inside the piezoelectric element package may be adjusted. Therefore, there may arise no problem that a frequency shift occurs to make the product defective after manufacturing as in the past, and manufacturing yield may be improve.

### BRIEF DESCRIPTION OF THE DRAWINGS

The invention will be described with reference to the accompanying drawings, wherein like numbers reference like elements.

FIG. 1A is a front part cross sectional view illustrating a constitution of a crystal oscillation as a piezoelectric device.

FIG. 1B is a side part cross sectional view illustrating the constitution of the crystal oscillation as a piezoelectric device.

FIG. 2 is a flowchart showing a manufacturing process of the crystal oscillation.

FIG. 3A is a front part cross sectional view illustrating an embodiment for manufacturing a plurality of crystal oscillations from one substrate.

FIG. 3B is a side part cross sectional view illustrating the embodiment for manufacturing a plurality of crystal oscillations from one substrate.

FIG. 4A is a front part cross sectional view illustrating a constitution of a crystal oscillation in a third embodiment.

FIG. 4B is a side part cross sectional view illustrating the constitution of the crystal oscillation in the third embodiment.

FIG. 5 is a flowchart showing a manufacturing process of the crystal oscillation in a fourth embodiment.

FIG. 6A is a front part cross sectional view illustrating an embodiment for manufacturing a plurality of crystal oscillations from one substrate.

FIG. 6B is a side part cross sectional view illustrating the embodiment for manufacturing a plurality of crystal oscillations from one substrate.

FIG. 7 is an illustrative drawing illustrating adjustment of a frequency.

FIG. 8A is a front part cross sectional view illustrating a constitution of another crystal oscillation as a fifth embodiment.

FIG. 8B is a side part cross sectional view illustrating the constitution of another crystal oscillation as the fifth embodiment.

FIG. 9 is a flowchart showing a manufacturing process of another crystal oscillation as a sixth embodiment.

FIG. 10A is a front part cross sectional view illustrating an embodiment for manufacturing a plurality of crystal oscillations from one substrate.

FIG. 10B is a side part cross sectional view illustrating the embodiment for manufacturing a plurality of crystal oscillations from one substrate.

FIG. 11 is an illustrative drawing illustrating adjustment of a frequency

### DESCRIPTION OF EXEMPLARY EMBODIMENTS

Embodiments embodying the present invention will now be described with reference to the drawings. In the following embodiments, a crystal oscillation as a piezoelectric device will be explained as an example.

### First Embodiment

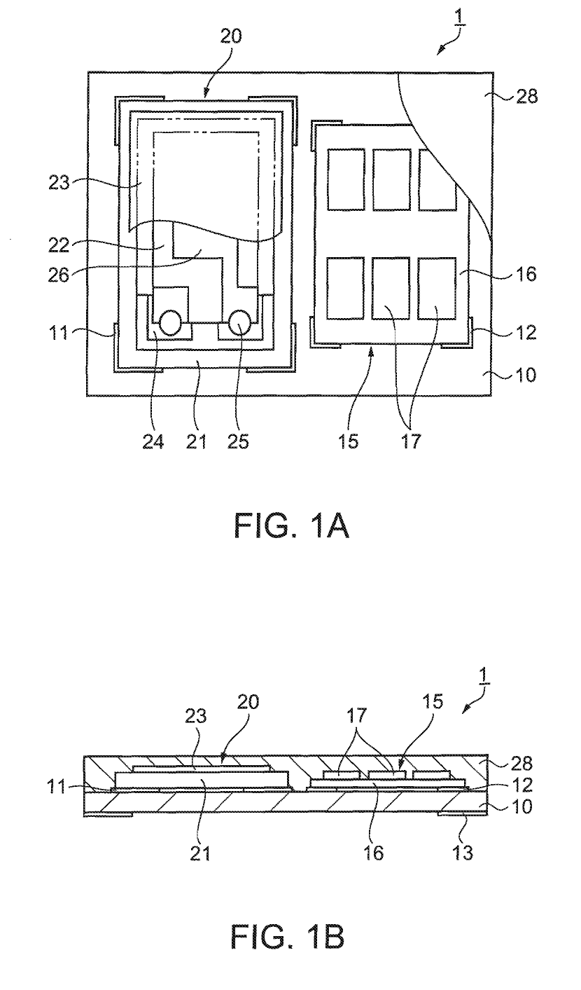

FIGS. 1A and 1B are illustrative drawings illustrating a constitution of a crystal oscillation as a piezoelectric device. FIG. 1A is a front part cross sectional view, and FIG. 1B is a side part cross sectional view.

A crystal oscillation 1 is provided with a substrate 10, a circuit module 15, a crystal unit package 20 as a piezoelectric element package, and a resin member 28 covering the circuit module 15 and the crystal unit package 20.

The substrate 10 is made of glass epoxy resin and the like, and has a wiring pattern formed thereon. For example, the substrate has a terminal 12 and a terminal 11 formed thereon on which the circuit module 15 and the crystal unit package 20 are set, respectively Further, an external terminal 13 is formed on the other surface side of the substrate in order to connect to the outside. Each of the terminals is constituted so as to be connected electrically by a predetermined wiring pattern.

The circuit module 15 is formed in which a plurality of circuit elements 17 (an IC, transistor, resistance, capacitor, thermistor, etc.) are soldered to a module substrate 16 made of grass epoxy resin and the like. These circuit elements 17 constitute an oscillation circuit for oscillating a crystal oscillation piece described later, a temperature compensation circuit, or the like.

The crystal unit package 20 is formed in which a crystal oscillation piece 22 as a piezoelectric element is housed in a housing 21 made of ceramic or the like. An electrode 26 is formed on the crystal oscillation piece 22. The electrode 26 and a terminal 24 formed in the housing 21 are affixed via an electrically conductive adhesive 25. A lid 23 on the housing 21 seals the package to maintain the inside thereof in a vacuum atmosphere or an inert gas atmosphere.

The circuit module 15 and the crystal unit package 20 are set on one surface side of the substrate 10 by soldering and the like. The resin member 28 is formed to cover the circuit module 15 and the crystal unit package 20. The resin member 28 is made of epoxy resin and the like, and formed by resin-molding by use of a transfer molding apparatus.

As described above, in the crystal oscillation 1 of the first embodiment, since the circuit elements 17 can be mounted on the module substrate 16 in advance, a heating condition for a reflow and others can be matched with the circuit elements 17. Therefore, the defective soldering can be reduced. The crystal unit package 20 and the circuit module 15 may be set on the substrate 10 of the crystal oscillation 1 thereafter. There is no require for soldering again due to the defective soldering of the circuit elements 17. In this manner, it is possible to improve the productivity of manufacturing the crystal oscillation 1 and provide the crystal oscillation 1 with less frequency shift when setting the crystal unit package 20 on the substrate 10, and excellent characteristics.

Furthermore, since the resin member 28 is formed so as to cover the crystal unit package 20 and the circuit module 15 from the substrate 10, it plays a role of reinforcing the substrate 10 even if the substrate 10 is made thinner. Therefore, while maintaining strength as the crystal oscillation 1, a thickness thereof can be reduced.

### Second Embodiment

Next, a method of manufacturing the crystal oscillation as the piezoelectric device will be described. Note that, the same elements explained in the first embodiment are designated by like numerals, and the description will be omitted.

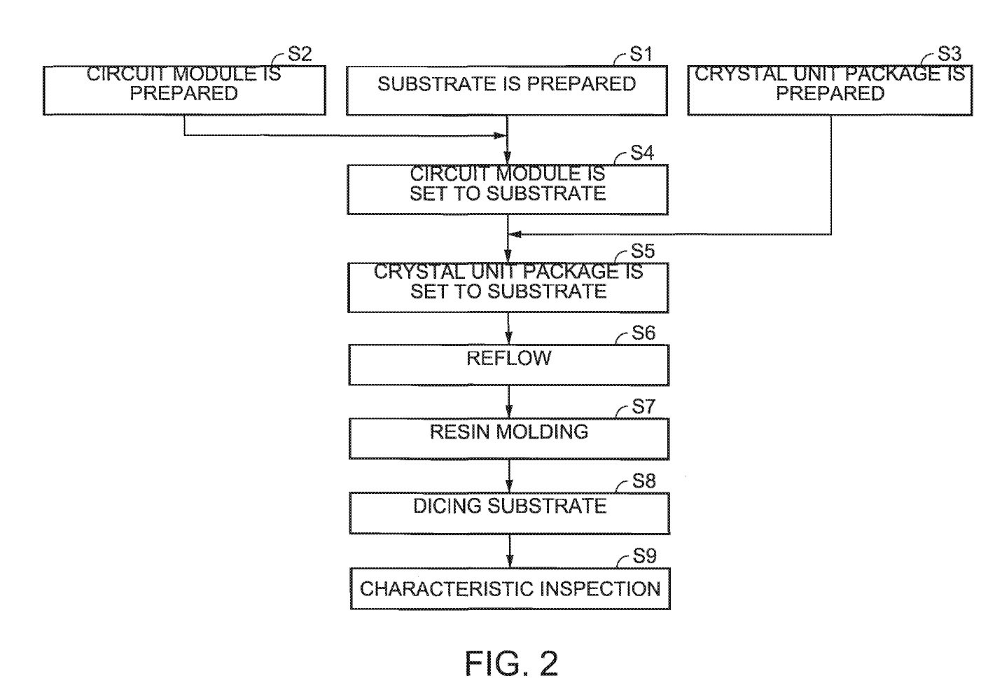

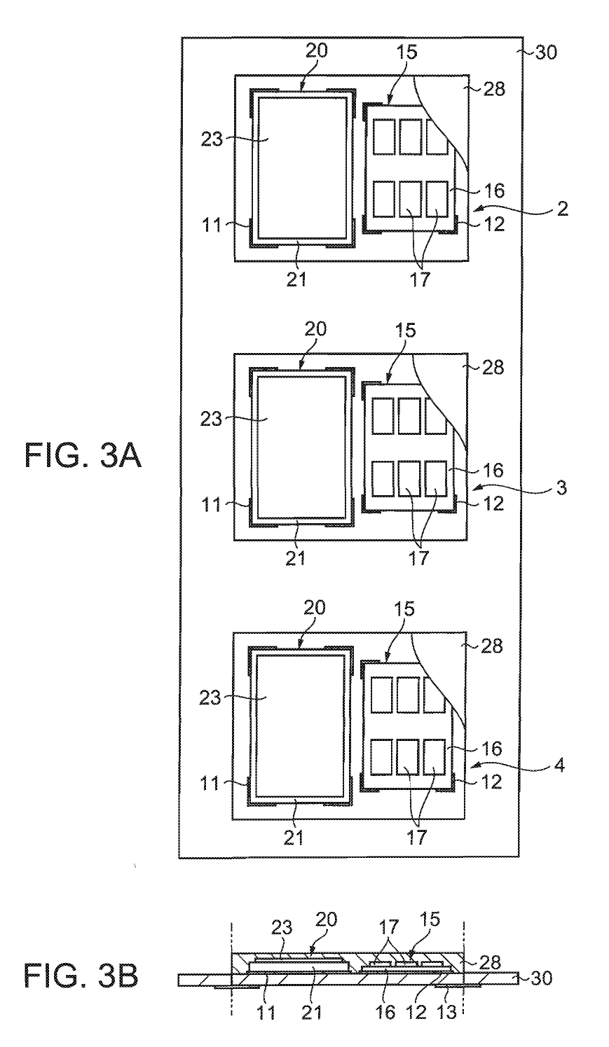

FIG. 2 is a flowchart showing a manufacturing process of the crystal oscillation. FIGS. 3A and 3B are illustrative drawings showing an embodiment for manufacturing a plurality of crystal oscillations from one substrate. FIG. 3A is a front part cross sectional view. FIG. 3B is a side part cross sectional view.

The method of manufacturing the crystal oscillation will be described by use of FIGS. 3A and 3B in the order of the flowchart in FIG. 2.

First, a substrate 30 is prepared on which a plurality of wiring patterns are formed (Step S1). Circuit modules 15 are prepared in each of which circuit elements 17 are soldered to a module substrate 16 (Step S2). Crystal unit packages 20 are prepared in each of which a crystal oscillation piece is housed and a frequency is set to a predetermined frequency (Step S3).

Solder cream is applied to each of terminals 12 in the substrate 30 on which the circuit module 15 is to be set, and the circuit modules 15 are set (Step S4).

Next, solder cream is applied to each of terminals 11 in the substrate 30 on which the crystal unit package 20 is set, and the crystal unit packages 20 are set (Step S5).

The substrate 30 is made to pass through a reflow furnace, and each of the circuit modules 15 and each of the crystal unit packages 20 are soldered to the substrate 30 (Step S6).

Thereafter, resin-molding is performed on one surface side of the substrate 30 by the transfer molding apparatus to form a resin member 28 so as to cover each of the circuit modules 15 and each of the crystal unit packages 20 (Step S7).

Then, the substrate 30 is cut by dicing along the resin member 28 resin-molded to separate crystal oscillations 2, 3 and 4 into individual pieces (Step S8).

Finally, characteristics of the individualized crystal oscillations 2, 3 and 4 are inspected (Step S9), and the crystal oscillations 2, 3 and 4 are completed.

According to the above-described method of manufacturing the crystal oscillation 2, 3 and 4, setting the circuit elements 17 on the substrate 30 is made by setting the circuit module 15 which has mounted the circuit elements 17 in advance. Therefore, the crystal oscillation 2, 3 and 4 may be easily assembled. Further, there is no require for soldering again due to the defective soldering of the circuit elements 17, and productivity is improved.

Further, the plural crystal oscillations 2, 3 and 4 are manufactured on one substrate, i.e. substrate 30 by fixing the circuit modules 15 and the crystal unit packages 20, and resin-molding. Finally the crystal oscillations 2, 3 and 4 are cut into individual pieces by dicing or the like. Therefore, productivity can be further improved.

In the above-described embodiment, the description is given to an embodiment in which a plurality of crystal oscillations are manufactured on one substrate. It is also possible to manufacture one crystal oscillation on one substrate.

In the manufacturing method also, setting the circuit elements on the substrate of the crystal oscillation is made by setting the circuit module which has mounted the circuit elements in advance. Therefore, the piezoelectric device may be easily assembled. Further, there is no require for soldering again due to the defective soldering of the circuit elements, and productivity can be improved. In this case, dicing of the substrate is not needed, therefore, it is possible to simplify the processes and reduce the equipments.

### Third Embodiment

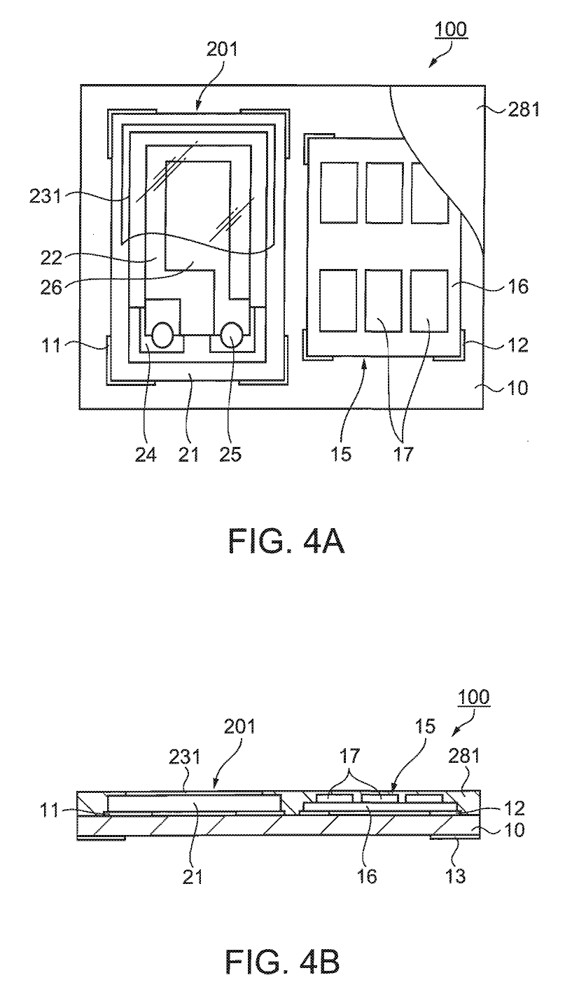

FIGS. 4A and 4B are illustrative drawings illustrating a constitution of a crystal oscillation as a piezoelectric device. FIG. 4A is a front part cross sectional view. FIG. 4B is a side part cross sectional view.

A crystal oscillation 100 is provided with a substrate 10, a circuit module 15, a crystal unit package 201 as a piezoelectric element package, and a resin member 281 covering the circuit module 15 and the crystal unit package 201.

The substrate 10 is made of glass epoxy resin and the like, and has a wiring pattern formed thereon. The substrate 10 has, on one surface side thereof, a terminal 12 and a terminal 11 formed on which the circuit module 15 and the crystal unit package 201 are set, respectively. Further, an external terminal 13 is formed on the other surface side of the substrate 10 in order to connect to the outside. Each of the terminals is constituted so as to be connected electrically by a predetermined wiring pattern.

The circuit module 15 is formed in which a plurality of circuit elements 17 (an IC, transistor, resistance, capacitor, thermistor, etc.) are soldered to a module substrate 16 made of grass epoxy resin and the like. These circuit elements 17 constitute an oscillation circuit for oscillating a crystal oscillation piece described later, a temperature compensation circuit, or the like.

The crystal unit package 201 is formed in which a crystal oscillation piece 22 as a piezoelectric element is housed in a housing 21 made of ceramic or the like. An electrode 26 is formed on the crystal oscillation piece 22. The electrode 26 and a terminal 24 formed in the housing 21 are affixed via an electrically conductive adhesive 25. A glass lid (lid member) 231 having optical transparency on the housing 21 seals the package to maintain the inside thereof in a vacuum atmosphere or an inert gas atmosphere. The glass lid 231 made of a thin plate glass, and for example, borosilicate glass is used.

The circuit module 15 and the crystal unit package 201 are set on one surface side of the substrate 10 by soldering and the like. The resin member 281 is formed to cover the circuit module 15 and the crystal unit package 201. The resin member 281 is formed such that the upper surface of the glass lid 231 of the crystal unit package 201 is exposed to the outside. Here, in the third embodiment, the upper surface of the glass lid 231 and the upper surface of the resin member 281 are entirely the same level. However, all the upper surface of the glass lid 231 is not required to be exposed, and at least a part of glass lid 231 may be exposed which positions above the electrode 26 of a portion which relates to oscillation of the crystal oscillation piece 22 housed in the crystal unit package 201.

The resin member 281 is made of epoxy resin and the like, and formed by molding by use of a transfer molding apparatus.

As described above, the transparent glass lid 231 of the crystal unit package 201 is formed so as to be exposed to the outside. Therefore, even after assembling the crystal oscillation 100, the frequency can be adjusted by irradiating laser beam to the inside of the package from the outside through the glass lid 231 thereby to remove a part of the electrode formed on the crystal oscillation piece 22 in the crystal unit package 201.

In this manner, the frequency can be adjusted easily after assembling the crystal oscillation 100, which has been impossible in the past. Therefore, it is possible to provide the crystal oscillation 100 the frequency of which can be set to a desired frequency even when a high frequency accuracy is required.

Furthermore, according to the constitution of the third embodiment, the resin member 281 is formed such that it covers the crystal unit package 201 and the circuit module 15 from the substrate 10, and the transparent glass lid 231 of the crystal unit package 201 is exposed to the outside. A total thickness of the crystal oscillation 100 is the thickness of the substrate 10 and the thickness of the crystal unit package 201 added together. Thus, the thickness of the crystal oscillation 100 can be reduced. Further, the resin member 281 plays a role of reinforcing the substrate 10 even if the substrate is made thinner. Thus, a thickness of the crystal oscillation 100 can be further reduced while maintaining strength thereof.

### Fourth Embodiment

Next, a method of manufacturing the crystal oscillation described in the first embodiment will be described. Note that, the same elements explained in the first embodiment are designated by like numerals, and the description will be given.

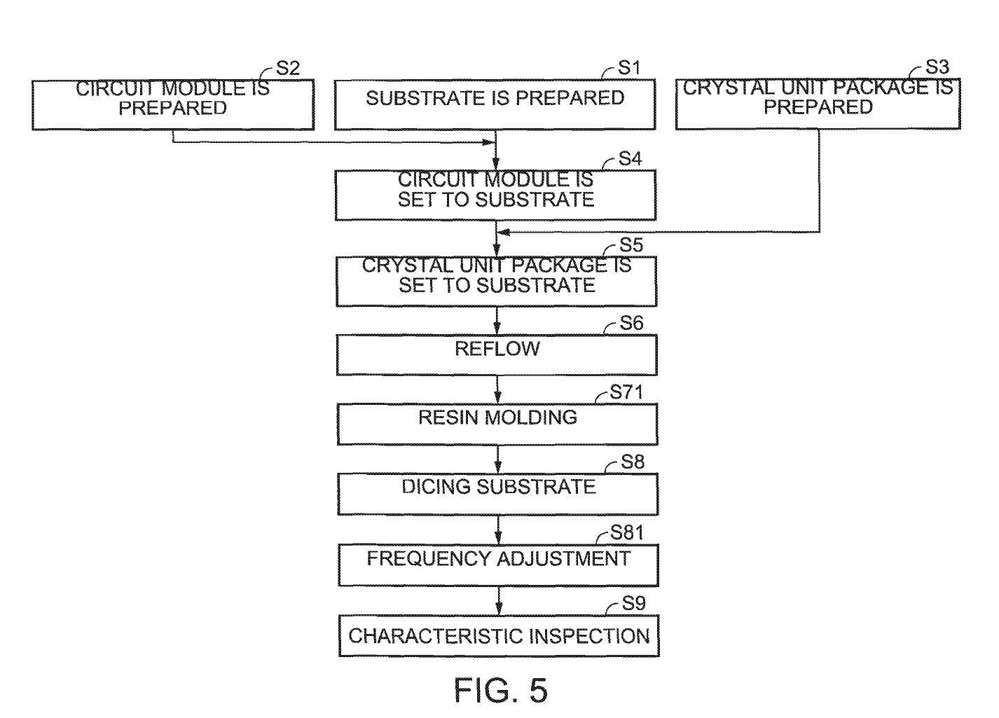

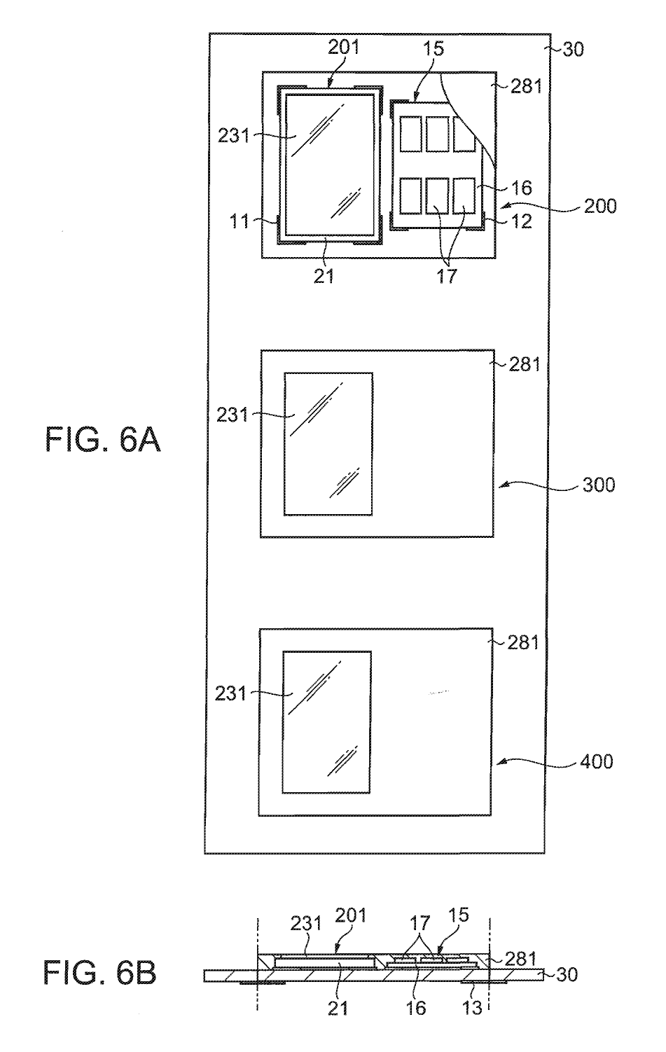

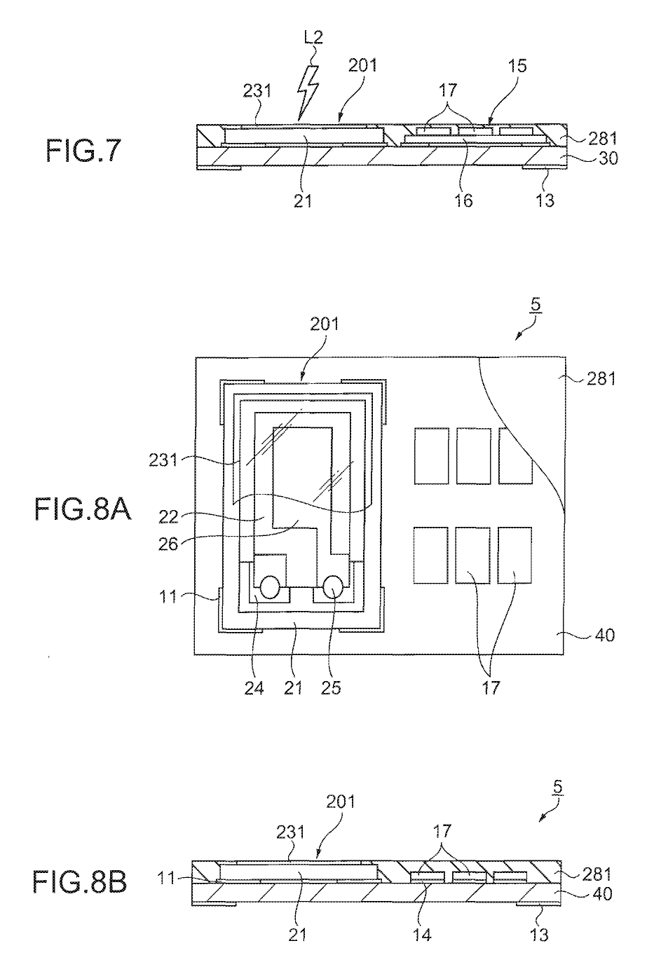

FIG. 5 is a flowchart showing a manufacturing process of the crystal oscillation. FIGS. 6A and 6B are illustrative drawings showing an embodiment for manufacturing a plurality of crystal oscillations from one substrate. FIG. 6A is a front part cross sectional view. FIG. 6B is a side part cross sectional view.

The method of manufacturing the crystal oscillation will be described by use of FIGS. 6A and 6B in the order of the flowchart in FIG. 5.

First, a substrate 30 is prepared on which a plurality of wiring patterns are formed (Step S1). Circuit modules 15 are prepared in each of which circuit elements 17 are soldered to a module substrate 16 (Step S2). Crystal unit packages 201 are prepared in each of which a crystal oscillation piece 22 is housed and a frequency is set to a predetermined frequency (Step S3).

Solder cream is applied to each of terminals 12 in the substrate 30 on which the circuit module 15 is to be set, and the circuit modules 15 are set (Step S4).

Next, solder cream is applied to each of terminals 11 in the substrate 30 on which the crystal unit package 201 is to be set, and the crystal unit packages 201 are set (Step 55).

The substrate 30 is made to pass through a reflow furnace, and each of the circuit modules 15 and each of the crystal unit packages 201 are soldered to the substrate 30 (Step S6).

Thereafter, resin-molding is performed on one surface side of the substrate 30 by the transfer molding apparatus to form a resin member 281 such that each of the circuit modules 15 and each of the crystal unit packages 201 are covered, and the transparent glass lid 231 of the crystal unit package 201 is exposed to the outside (Step S71).

Then, the substrate 30 is cut by dicing along the resin member 281 resin-molded to separate crystal oscillations 200, 300 and 400 into individual pieces (Step S8).

After that, the frequency is adjusted by irradiating laser beam L2 to the inside of the package from the outside through the glass lid 231 exposed to the outside thereby to remove a part of the electrode formed on the crystal oscillation piece 22 in the crystal unit package 201 (Step S81).

Finally, characteristics of the individualized crystal oscillations 200, 300 and 400 are inspected (Step S9), and the crystal oscillations 200, 300 and 400 are completed.

In the method of manufacturing the crystal oscillations 200, 300 and 400, the transparent glass lid 231 of the crystal unit package 201 is formed so as to be exposed to the outside, in resin-molding in a state of fixing the crystal unit packages 201 and the circuit modules 15 to the substrate 30. Thus, the frequency can be adjusted by irradiating the laser beam L2 to the inside of the package from the outside through the glass lid 231 thereby to remove a part of the electrode on the crystal oscillation piece 22 in the crystal unit package 201.

Further, a plurality of crystal oscillations are manufactured on one substrate by fixing the circuit modules and the piezoelectric element packages, and resin-molding. Thereafter, the crystal oscillations are cut into individual pieces by dicing or the like. Therefore, productivity may be further improved.

In the above-described embodiment, the description is given to an embodiment in which a plurality of crystal oscillations are manufactured on one substrate. It is also possible to manufacture one crystal oscillation on one substrate.

In this manufacturing method also, the transparent glass lid 231 of the crystal unit package 201 is formed so as to be exposed to the outside, in resin-molding in a state of fixing the crystal unit packages 201 and the circuit modules 15 to the substrate 30. Thus, the frequency can be adjusted by irradiating the laser beam L2 to the inside of the package from the outside through the glass lid 231 thereby to remove a part of the electrode formed on the crystal oscillation piece 22 in the crystal unit package 201.

### Fifth Embodiment

Next, another embodiment of a crystal oscillation of a piezoelectric device will be described. In the embodiment, circuit elements are directly set on a substrate of a crystal oscillation.

FIGS. 8A and 8B are illustrative drawings illustrating a constitution of the crystal oscillation. FIG. 8A is a front part cross sectional view. FIG. 8B is a side part cross sectional view. Note that, the same elements explained in the first embodiment are designated by like numerals.

A crystal oscillation 5 is provided with a substrate 40, circuit elements 17, a crystal unit package 201 as a piezoelectric element package, and a resin member 281 covering the circuit elements 17 and the crystal unit package 201.

The substrate 40 is made of glass epoxy resin and the like, and has a wiring pattern formed thereon. The substrate 40 has, on one surface side thereof, a terminal 14 and a terminal 11 formed on which the circuit elements 17 and the crystal unit package 201 are set, respectively. Further, an external terminal 13 is formed on the other surface side of the substrate 40 in order to connect to the outside. Each of the terminals is constituted so as to be connected electrically by a predetermined wiring pattern.

A plurality of circuit elements 17 (an IC, transistor, resistance, capacitor, thermistor, etc.) are soldered to the substrate 40. These circuit elements 17 constitute an oscillation circuit for oscillating a crystal oscillation piece described later, a temperature compensation circuit, or the like.

The crystal unit package 201 is formed in which a crystal oscillation piece 22 as a piezoelectric element is housed in a housing 21 made of ceramic or the like. An electrode 26 is formed on the crystal oscillation piece 22. The electrode 26 and a terminal 24 formed in the housing 21 are affixed via an electrically conductive adhesive 25. A glass lid 231 having optical transparency on the housing 21 seals the package to maintain the inside thereof in a vacuum atmosphere or an inert gas atmosphere. The glass lid 231 made of a thin plate glass, and for example, borosilicate glass is used.

The circuit elements 17 and the crystal unit package 201 are set on one surface side of the substrate 40 by soldering and the like. The resin member 281 is formed to cover the circuit elements 17 and the crystal unit package 201. The resin member 281 is formed such that the upper surface of the glass lid 231 of the crystal unit package 201 is exposed to the outside. Here, in the fifth embodiment, the upper surface of the glass lid 231 and the upper surface of the resin member 281 are entirely the same level. However, all the upper surface of the glass lid 231 is not required to be exposed, and at least a part of glass lid 231 may be exposed which positions above the electrode 26 of a portion which relates to oscillation of the crystal oscillation piece 22 housed in the crystal unit package 201.

The resin member 281 is made of epoxy resin and the like, and formed by molding by use of a transfer molding apparatus.

As described above, the transparent glass lid 231 of the crystal unit package 201 is formed so as to be exposed to the outside. Therefore, even after assembling the crystal oscillation 5, the frequency can be adjusted by irradiating laser beam to the inside of the package from the outside through the glass lid 231 thereby to remove a part of the electrode formed on the crystal oscillation piece 22 in the crystal unit package 201.

In this manner, the frequency can be adjusted easily after assembling the crystal oscillation 5, which has been impossible in the past. Therefore, it is possible to provide the crystal oscillation 5 the frequency of which can be set to a desired frequency even when a high frequency accuracy is required.

Furthermore, according to the constitution of the fifth embodiment, the resin member 281 is formed such that it covers the crystal unit package 201 and the circuit elements 17 from the substrate 40, and the transparent glass lid 231 of the crystal unit package 201 is exposed to the outside. A total thickness of the crystal oscillation 5 is the thickness of the substrate 40 and the thickness of the crystal unit package 201 added together. Thus, the thickness of the crystal oscillation D can be reduced. Further, the resin member 281 plays a role of reinforcing the substrate 40 even if the substrate 40 is made thinner. Thus, a thickness of the crystal oscillation 5 can be further reduced while maintaining strength thereof.

### Sixth Embodiment

Next, a method of manufacturing the crystal oscillation described in the third embodiment will be described. Note that, the same elements explained in the third embodiment are designated by like numerals, and the description will be given.

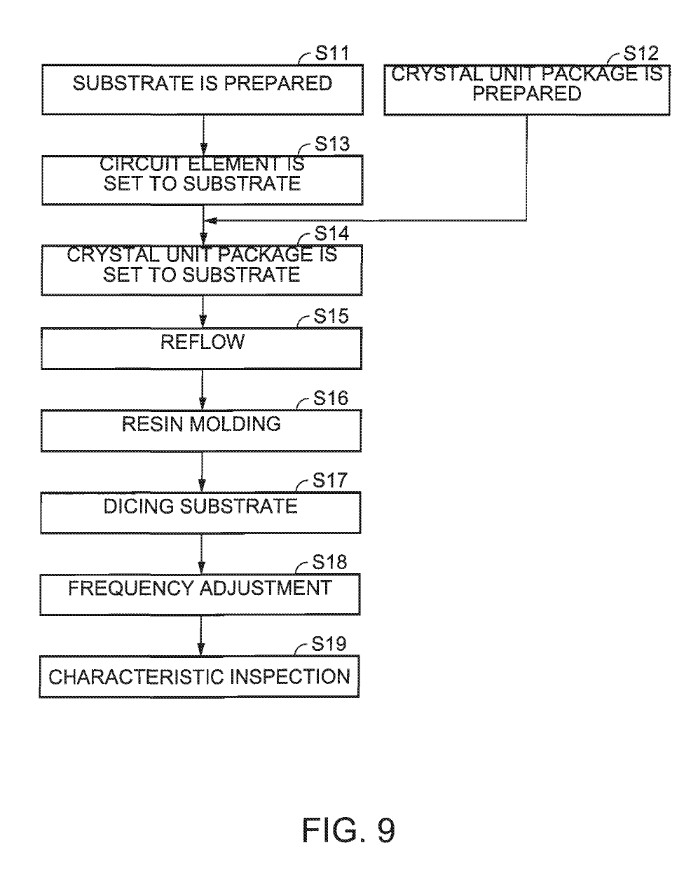

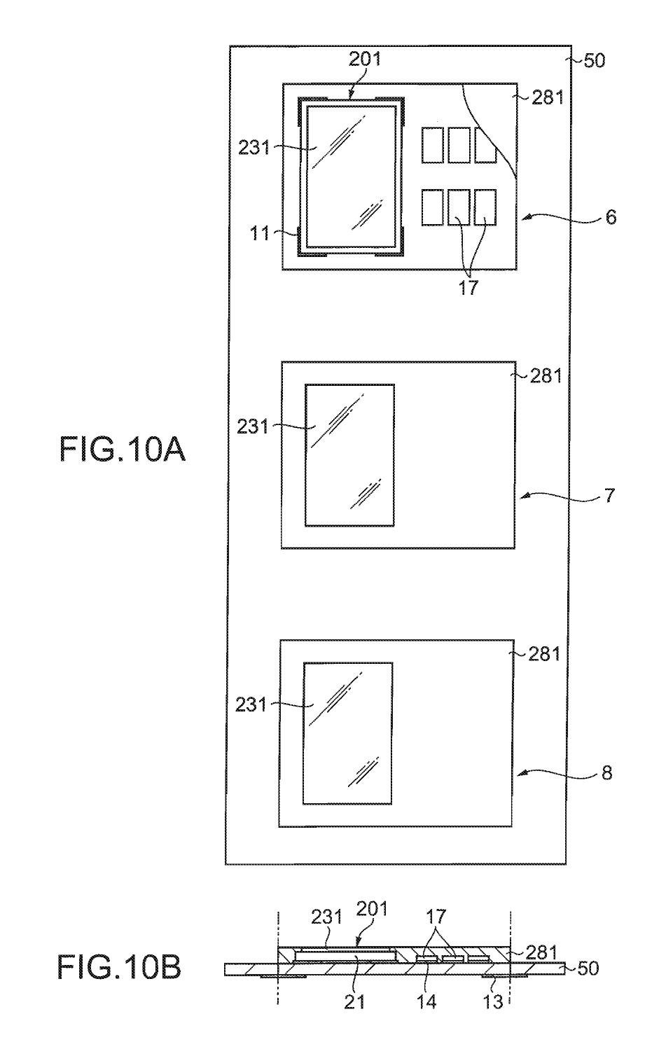

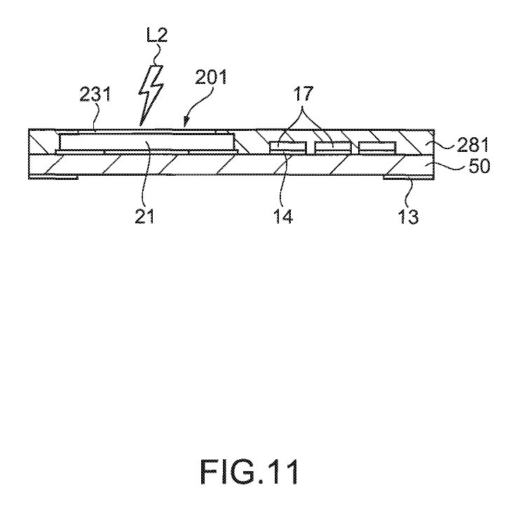

FIG. 9 is a process flowchart showing a manufacturing process of the crystal oscillation. FIGS. 10A and 10B are illustrative drawings showing an embodiment for manufacturing a plurality of crystal oscillations from one substrate. FIG. 10A is a front part cross sectional view. FIG. 10B is a side part cross sectional view.

The method of manufacturing the crystal oscillation will be described by use of FIGS. 10A and 10B in the order of the process flowchart in FIG. 9.

First, a substrate 50 is prepared on which a plurality of wiring patterns are formed (Step S11). Crystal unit packages 201 are prepared in each of which a crystal oscillation piece 22 is housed and a frequency is set to a predetermined frequency (Step S12).

Solder cream is applied to each of terminals in the substrate 50 on which a circuit element 17 is to be set, and the circuit elements 17 are set (Step S13).

Next, solder cream is applied to each of terminals 11 in the substrate 50 on which the crystal unit package 201 is set, and the crystal unit packages 201 are set (Step S14).

The substrate 50 is made to pass through a reflow furnace, and each of the circuit elements 17 and each of the crystal unit packages 201 are soldered to the substrate 50 (Step S15).

Thereafter, resin-molding is performed on one surface side of the substrate 50 by the transfer molding apparatus to form a resin member 281 such that each of the circuit elements 17 and each of the crystal unit packages 201 are covered, and the transparent glass lid 231 of the crystal unit package 201 is exposed to the outside (Step S16).

Then, the substrate 50 is cut by dicing along the resin member 281 resin-molded to separate crystal oscillations 6, 7 and 8 into individual pieces (Step S17).

After that, the frequency is adjusted by irradiating laser beam L2 to the inside of the package from the outside through the glass lid 231 thereby to remove a part of the electrode formed on the crystal oscillation piece 22 in the crystal unit package 201 (Step S18).

Finally, characteristics of the individualized crystal oscillations 6, 7 and 8 are inspected (Step S19), and the crystal oscillations 6, 7 and 8 are completed.

In the method of manufacturing the crystal oscillations 6, 7 and 8, the transparent glass lid 231 of the crystal unit package 201 is formed so as to be exposed to the outside, in resin-molding in a state of fixing the crystal unit packages 201 and the circuit elements 17 to the substrate 50. Thus, the frequency can be adjusted by irradiating the laser beam L2 to the inside of the package from the outside through the glass lid 231 thereby to remove a part of the electrode on the crystal oscillation piece 22 in the crystal unit package 201.

Further, the plural crystal oscillations 6, 7, and 8 are manufactured on one substrate, i.e. substrate 50 by fixing the circuit elements 17 and the crystal unit packages 201, and resin-molding. Thereafter, the crystal oscillations 6, 7 and 8 are cut into individual pieces by dicing or the like. Therefore, productivity may be further improved.

In the above-described embodiment, the description is given to an embodiment in which a plurality of crystal oscillations are manufactured on one substrate. It is also possible to manufacture one crystal oscillation on one substrate,

In this manufacturing method also, the transparent glass lid 231 of the crystal unit package 201 is formed so as to be exposed to the outside, in resin-molding in a state of fixing the crystal unit packages 201 and the circuit elements 17 to the substrate. Thus, the frequency can be adjusted by irradiating the laser beam L2 to the inside of the package from the outside through the glass lid 231 thereby to remove a part of the electrode formed on the crystal oscillation piece 22 in the crystal unit package 201.

The piezoelectric device of the embodiments of the invention can be applied to, for example, a temperature compensated x′tal oscillator (TCXO). The frequency of the TCXO is set severely with frequency deviation. The TCXO is a piezoelectric device in which frequency change due to ambient temperature change and secular change is small, and is widely applied to mobile communication devices in recent years. In the constitution of the embodiments, it is possible to suppress a frequency shift of the oscillation device to be smaller, and reduce the thickness of the device further. Therefore, the device of the embodiments can be expected to be used for the TCXO.

Further, the embodiments of the invention can be applied not only as the oscillator which is provided with the piezoelectric element and the oscillation circuit, but also as piezoelectric device which is provided with another circuit elements but includes no the piezoelectric element nor the oscillation circuit.

In the embodiments, a glass epoxy substrate is used as the substrates of the crystal oscillation and the module, but a ceramic substrate may be used.

Moreover, in the embodiments of the invention, the crystal oscillation is exemplified as the piezoelectric device and the description is given. However, the piezoelectric device may be provided with the circuit elements and the oscillation device using piezoelectric materials such as lithium tantalate and lithium niobate as the piezoelectric element other than crystal. Furthermore, the embodiment of the invention can be embodied as a SAW oscillator having a SAW resonator in place of the oscillation device.

The entire disclosure of Japanese Patent Application Nos: 2005-215474, filed Jul. 26, 2005 and 2005-215475, led Jul. 26, 2005 are expressly incorporated by reference herein.

What is claimed is:

1. A piezoelectric device, comprising:
a substrate having a wiring pattern;
a piezoelectric element package disposed on one surface side of the substrate and having a piezoelectric element housed therein;
a circuit module, in which a module substrate mounts a circuit element, disposed on one surface side of the substrate; and
a resin member covering the piezoelectric element package and the circuit module from the substrate.

2. The piezoelectric device according to claim 1, wherein the piezoelectric element package has a transparent lid member at least a part of which is exposed to the outside.

3. A method of manufacturing a piezoelectric device, in which a substrate having a plurality of wiring patterns of a piezoelectric device disposed thereon is prepared, the method comprising:
fixing a circuit module in which a module substrate mounts a circuit element to each of the wiring patterns on one surface side of the substrate;
fixing a piezoelectric element package having a piezoelectric element housed therein to each of the wiring patterns on one surface side of the substrate;
performing resin-molding so as to cover the circuit module and the piezoelectric element package of each of the piezoelectric devices; and
cutting the substrate into a plurality of piezoelectric devices.

4. The method of manufacturing a piezoelectric device according to claim 3, wherein in resin-molding, the circuit module and the piezoelectric element package of each of the piezoelectric devices is resin-molded such that at least a part of a transparent lid member of the piezoelectric element package is exposed to the outside.

5. The method of manufacturing a piezoelectric device according to claim 4, wherein in a stage after resin-molding, a frequency of the piezoelectric element is adjusted by irradiating laser beam to the inside of the package through the transparent lid member exposed to the outside.

6. A method of manufacturing a piezoelectric device, in which a substrate having a wiring pattern disposed thereon is prepared, comprising:
fixing a circuit module in which a module substrate mounts a circuit element to the wiring pattern on one surface side of the substrate;
fixing a piezoelectric element package having a piezoelectric element housed therein to the wiring pattern on one surface side of the substrate; and
performing resin-molding so as to cover the circuit module and the piezoelectric element package.

7. A piezoelectric device, comprising:
a substrate having a wiring pattern;
a piezoelectric element package which is disposed on one surface side of the substrate, has a piezoelectric element housed therein, and is provided with a transparent lid member;
a circuit element disposed on one surface side of the substrate; and
a resin member covering the piezoelectric element package and the circuit element from the substrate,
wherein at least a part of the transparent lid member of the piezoelectric element package is exposed to the outside.

8. A method of manufacturing a piezoelectric device, in which a substrate having a wiring pattern disposed thereon is prepared, comprising:
fixing a circuit element to one surface side of the substrate;
fixing a piezoelectric element package having a piezoelectric element housed therein to one surface side of the substrate; and
performing resin-molding the circuit element and the piezoelectric element package such that at least a part of a transparent lid member of the piezoelectric element package is exposed to the outside.

9. The method of manufacturing a piezoelectric device according to claim 8, wherein in a stage after resin-molding, a frequency of the piezoelectric element is adjusted by irradiating laser beam to the inside of the package through the transparent lid member exposed to the outside.

10. A method of manufacturing a piezoelectric device, in which a substrate having a plurality of wiring patterns of a piezoelectric device disposed thereon is prepared, the method comprising:
fixing a circuit element to each of the wiring patterns on one surface side of the substrate;
fixing a piezoelectric element package having a piezoelectric element housed therein to each of the wiring patterns on one surface side of the substrate;
performing resin-molding the circuit element and the piezoelectric element package of each of the piezoelectric devices such that at least a part of a transparent lid member of the piezoelectric element package is exposed to the outside; and
cutting the substrate into a plurality of piezoelectric devices.

11. The method of manufacturing a piezoelectric device according to claim 10, wherein in a stage after resin-molding, a frequency of the piezoelectric element is adjusted by irradiating laser beam to the inside of the package through the transparent lid member exposed to the outside.
